(19) United States
(12) Patent Application Publication
(10) Pub. No.: US 2019/0324070 A1
(43) Pub. Date: Oct. 24, 2019

(54) STATE ESTIMATION APPARATUS, STATE ESTIMATION METHOD, AND NON-TRANSITORY MEDIUM

(71) Applicant: NEC Corporation, Minato-ku, Tokyo (JP)

(72) Inventors: Eisuke SANEYOSHI, Tokyo (JP); Shigeru KOUMOTO, Tokyo (JP); Akira SHOUJIGUCHI, Tokyo (JP)

(73) Assignee: NEC Corporation, Minato-ku, Tokyo (JP)

(21) Appl. No.: 16/463,011

(22) PCT Filed: Nov. 29, 2017
(86) PCT No.: PCT/JP2017/042911

§ 371 Date: May 22, 2019

(30) Foreign Application Priority Data
Nov. 30, 2016 (JP) 2016-232237

(51) Int. Cl. G01R 21/133; H02J 13/00

(52) U.S. Cl. CPC G01R 21/133; H02J 13/0017

(57) ABSTRACT

The present invention extracts a time segment of an analysis target from time series data of a signal related to an operation of the facility and estimates a change with time of a state of the facility, based on the time series data of the time segment extracted.

### REFERENCE TO RELATED APPLICATION

The present disclosure is based upon and claims the benefit of the priority of Japanese patent application No. 2016-232237, filed on Nov. 30, 2016, the disclosure of which is incorporated herein in its entirety by reference thereto.

### TECHNICAL FIELD

The present invention relates to an apparatus, a method, and a program for estimating a state of a facility.

### BACKGROUND

A deterioration state of an electrical facility (abbreviated as “facility”) progresses, with passage of time or years, according to use of the facility. Electro-migration (EM), for example, is a typical one of causes of the deterioration. Due to EM, corrosion may occur in a wiring pattern or the like on a circuit board provided in the facility, and quality of a power supply line or a signal transmission path may be degraded. Then, finally, normal power supply or normal signal transmission may become difficult in the facility, thereby leading to end of product life. Alternatively, depending on a type of usage or an environment of the facility, the facility may be broken before an end of a product life of the facility.

In a facility configured to perform heat exchange, such as a refrigeration facility, an air conditioning facility, or the like, a refrigerant gas is compressed by a compressor to become a high-temperature and high-pressure gas and is heat-exchanged with outdoor air by a condenser (outdoor heat exchanger). A refrigerant gas that gets partly liquefied by the condenser is pressure-reduced by an expansion valve, takes indoor heat away in an evaporator, and changes from a liquid to a gas. The refrigerant gas from the evaporator returns to the compressor again. Generally, the condenser (outdoor heat exchanger) of these air conditioning facilities includes a filter at an inlet to prevent entry of dust or the like. Besides a deterioration and a failure of an electrical circuit, a rotary machine system, or the like of the facility, an inflow amount or a discharge amount of air may be reduced due to clogging of the filter or the like as well, for example, thereby leading to a malfunction or a failure of the facility.

A periodical maintenance, for example, is carried out in order to avoid occurrence of a sudden failure of these facilities. However, in the case of the periodical maintenance, a maintenance interval (maintenance period) depends on the type of usage, the environment, or the like of the facility of a maintenance target as well. Therefore, it is difficult to set an appropriate interval of the periodical maintenance. If the interval of the periodical maintenance is short, for example, the cost for the maintenance increases. On the other hand, if the interval of the periodical maintenance is long, a problem occurs in terms of safety.

Then, a method may be used in which by monitoring, via a sensor (such as a current sensor, a power meter, a temperature sensor, a pressure sensor, or a vibration sensor) or the like, a state of the facility by a management apparatus or the like, which performs prediction and estimation of a deterioration state of the facility to determine necessity of maintenance. As a technology of installing a sensor or the like on a facility to be monitored to monitor a state of the facility, there are known the following related arts, for example.

Patent Literature 1 discloses an operating state determination apparatus by which even if a waveform of a voltage that is applied to an electric device is changed, an operating state of the electric device can be determined with high accuracy. This operating state determination apparatus acquires learning data associating, with one another, waveform data of a harmonic frequency current(s) included in a current that flows through a power supply line, operating state information indicating an operating state of the electric device when the waveform data is produced, and segment identification information configured to identify a preset waveform data comparison target segment in one AC voltage cycle of an AC voltage that is applied to the electric device. Then, the operating state determination apparatus determines an operating state of the electric device, based on a result of collation between the waveform data of the harmonic current associated with the acquired learning data and waveform data of a harmonic frequency current(s) measured by a harmonic frequency current measurement unit, in the waveform data comparison target segment.

Patent Literature 2 discloses a device identification apparatus and a device identification method by which a user can appropriately register a device and an operating mode of the device. That is, Patent Literature 2 discloses the device identification apparatus which is connected to a power meter configured to measure a current waveform of an electric device that consumes one or a plurality of electric powers and by which the operating mode of the electric device is identified from the current waveform. This device identification apparatus includes a measurement control unit configured to control a start and a stop of measurement of the current waveform of the electric device by the power meter, a measurement input unit configured to receive the current waveform that has been measured during a measurement period from the start to the stop, a waveform pattern extraction unit configured to extract one or a plurality of waveform patterns from the received current waveform, a pattern identification unit configured to classify the extracted one or the plurality of waveform patterns according to each operating mode, a registration unit configured to register the operating mode(s) with respect to the classified one or the plurality of waveform patterns, and an instruction unit to instruct the measurement control unit to start and stop the measurement of the current waveform and instruct the registration unit to register the operating mode(s) with respect to the one or the plurality of waveform patterns.

Further, as a technology of predicting a change with time of a state of a facility, the following related art, for example, is known.

Patent Literature 3 discloses a technology for enabling optimization without being influenced by a change with time component of an actual performance value that is used for the optimization and enabling prediction of a fluctuation in a near feature. That is, after a distribution has been defined as an evaluation function configured to evaluate a prediction output from a simulation model and an actual performance value that is obtained from an actual process with respect to input information given under a predetermined processing condition and a variation (variance or standard deviation) of a model error has been corrected, modification is performed using change with time information obtained by extracting the change with time component of the actual performance value. A near-future behavior of the process to be simulated is thereby predicted.

As a related art for determining individual states of a plurality of electric devices using one sensor, Non Patent Literature 1 describes, for example, estimation of power consumption for each device and determination of an operating state of the device by acquiring a waveform (such as an instantaneous waveform for each cycle) of a current that flows through a trunk line using one current sensor mounted on a distribution board and performing waveform analysis by referring to a waveform database including current waveform information peculiar to each device.

### CITATION LIST

### Patent Literature

### PTL 1

JP Patent Kokai Publication No. JP2013-044736A

### PTL 2

International Publication No. WO2013/157031A1

### PTL 3

JP Patent Kokai Publication No. JP-H07-056608A

### Non Patent Literature

### NPL 1

Shigeru Koumoto, Takahiro Toizumi, Eisuke Saneyoshi, “Power Fingerprint Analysis Technology for Visualizing Power Consumptions and Usage Situations of Multiple Devices by Using One Sensor”, NEC Technical Journal/Vol. 68, No. 2/Special Issue on Smart Energy Solution Led by ICT

### SUMMARY

### Technical Problem

As a sensor for sensing a state of a facility, a power meter, for example, can be installed on a distribution board or the like as well without being installed on or in a vicinity of the facility. Installing a sensor on a distribution board or the like, can avoid an increase in an introduction cost caused in case where a sensor (such as a power meter or a current sensor) is installed on an individual facility.

However, detection and estimation of a deterioration state of a facility using a power meter may have a problem in terms of accuracy or the like. That is, as will be described later, depending on a facility, it may also happen that a change with time (deterioration) does not appear as a significant difference in a power value until the deterioration state of the facility has considerably progressed and the facility has been brought into a failure or almost a failure state.

In this case, it is difficult to appropriately estimate a change with time of a state of the facility with practical accuracy, by monitoring a power value of the facility. If a deterioration state of the facility is to be appropriately detected based on power information, a high-performance power meter or high-performance arithmetic processing is needed.

The present invention has been conceived in view of the above-described problem, and an object of the present invention is to provide a state estimation apparatus, a state estimation method, and a program, each making it possible to suppress an increase in cost and estimate a change with time of a facility with a practical accuracy.

### Solution to Problem

According to the present invention, there is provided a state estimation apparatus comprising:

a first means that extracts, from time series data of a signal related to an operation of a facility, a time segment of an analysis target; and

a second means that estimates a change with time of a state of the facility, based on the time series data corresponding to the time segment extracted.

According to the present invention, there is provided a method of estimating a state of a facility by a computer, comprising:

a first step of extracting, from time series data of a signal related to an operation of the facility, a time segment of an analysis target; and

a second step of estimating a change with time of the state of the facility, based on time series data corresponding to the time segment extracted.

According to the present invention, there is provided a program configured to cause a computer to execute processing comprising:

extracting, from time series data of a signal related to an operation of a facility, a time segment of an analysis target; and

estimating a change with time of a state of the facility, based on the time series data of the time segment extracted.

According to the present invention, there is provided a computer-readable recording medium such as a semiconductor storage (e.g., a RAM (Random Access Memory), a ROM (Read Only Memory), an EEPROM (Electrically Erasable Programmable ROM, or the like), an HDD (Hard Disk Drive), a CD (Compact Disc), or a DVD (Digital Versatile Disc) that stores the above-described program therein.

### Advantageous Effects of Invention

According to the present invention, it is made possible to suppress an increase in cost and estimate a change with time of a facility with a practical accuracy.

### BRIEF DESCRIPTION OF THE DRAWINGS

FIG. 1 is a diagram illustrating an example of a configuration according to an example embodiment of the present invention.

FIG. 2 is a flow diagram illustrating operations according to the example embodiment of the present invention.

FIG. 3 is a graph explaining the example embodiment of the present invention.

FIG. 4 is a graph explaining the example embodiment of the present invention.

FIG. 5A is a graph explaining a relationship between a power value and a change with time.

FIG. 5B is a graph explaining a relationship between the power value and a degree of danger with respect to a failure.

FIG. 6A is a graph explaining a relationship between current information and a change with time.

FIG. 6B is a graph explaining a relationship between current information and a degree of danger with respect to failure.

FIG. 7 is a graph explaining an example.

FIG. 8 includes graphs explaining the example.

FIG. 9A is a diagram illustrating an example of the example embodiment of the present invention.

FIG. 9B is a diagram explaining an example of a sensor according to the example embodiment of the present invention.

FIG. 10A is a diagram explaining another example of the sensor according to the example embodiment of the present invention.

FIG. 10B includes graphs explaining waveform disaggregation.

FIG. 11 is a diagram illustrating the example embodiment of the present invention.

### DESCRIPTION OF EMBODIMENTS

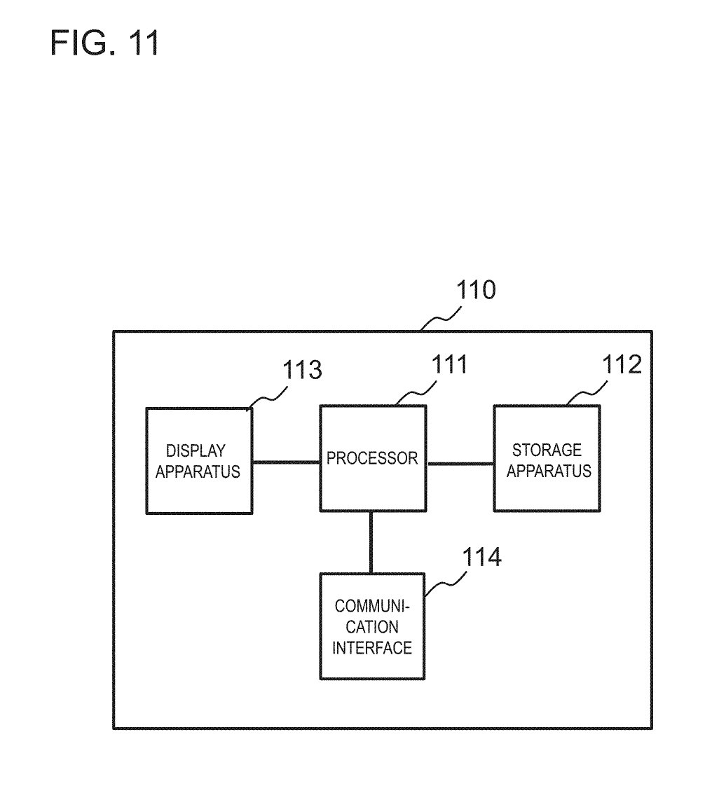

According to one aspect of the present invention, a processor (111 in FIG. 11, for example) executes a first process (first means, first unit, or first step) that extracts a time segment of an analysis target from time series data of a signal (of a power value or current information, for example) related to an operation of a facility; and a second process (second means, second unit, or second step) that estimates a change with time of a state of the facility, based on the time series data time series data of current information) of the time segment extracted.

In the first process (first means, first unit, or first step), a time segment corresponding to an operating mode that is not affected by the change with time may be excluded from the time series data of the signal related to the operation of the facility. In this case, in the first process (first means, first unit, or first step), the time segment corresponding to the operating mode that is not affected by the change with time may be excluded from the time series data of the signal related to the operation of the facility, based on operation history information of the facility. Alternatively, in the first process (first means, first unit, or first step), the time segment corresponding to the operating mode that is not affected by the change with time may be excluded from time series data of power or current of the facility, based on power information or current information of the facility.

The second process (second means, second unit, or second step), may be configured to estimate a change in a state of the facility from the time series data of current information of the facility corresponding to the time segment extracted and apply a filtering process corresponding to a time constant for a change with time of an extraction target with respect to the change in the state, thereby estimating the change with time of a state of the facility.

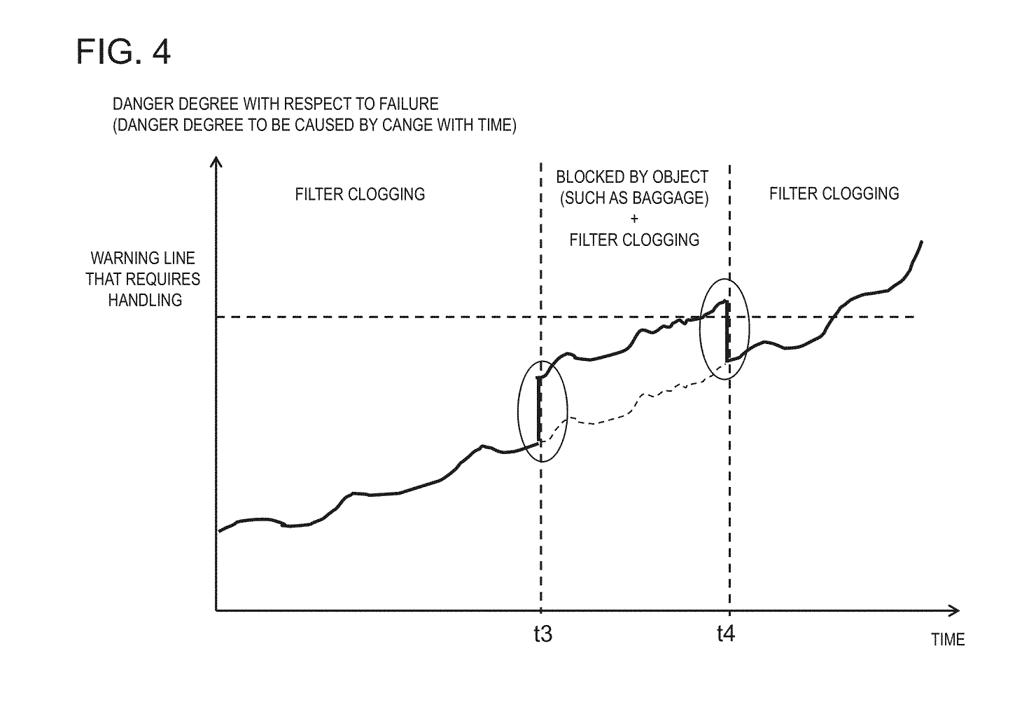

The second process (second means, second unit, or second step) may be configured to obtain time series data of a degree of danger with respect to a failure of the facility based on the time series data of current information of the facility corresponding to the time segment extracted and apply the filtering process corresponding to a time constant for a change with time of an extraction target to the time series data (refer to FIG. 4) of a degree of danger with respect to the failure corresponding to the time segment extracted to estimate the change with time of the state of the facility. The following describes example embodiments with reference to the drawings.

### Example Embodiment

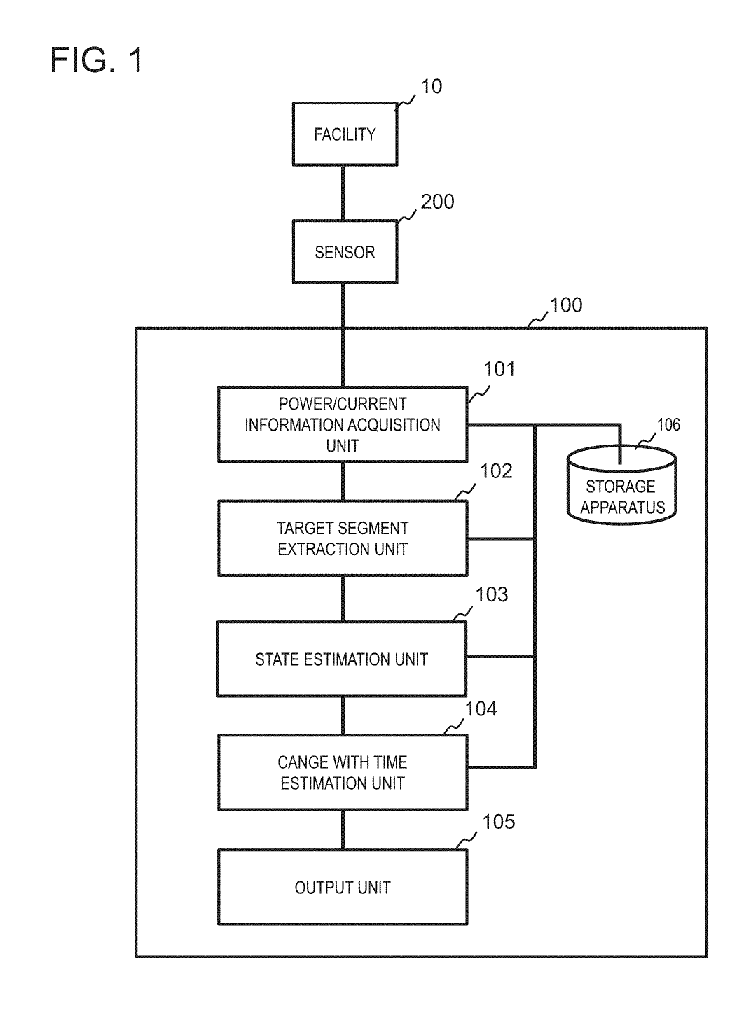

FIG. 1 is a diagram explaining an example embodiment of the present invention. Referring to FIG. 1, according to the example embodiment, a state estimation apparatus 100 configured to estimate a state of a facility includes a power/current information acquisition unit 101, a target segment extraction unit 102, a state estimation unit 103, a change with time estimation unit 104, an output unit 105, and a storage apparatus 106.

The target segment extraction unit 102 can be made to correspond to the first means (first unit) configured to execute the above-described first process. The state estimation unit 103 and the change with time estimation unit 104 can be made to correspond to the second means (second unit) configured to execute the above-described second process.

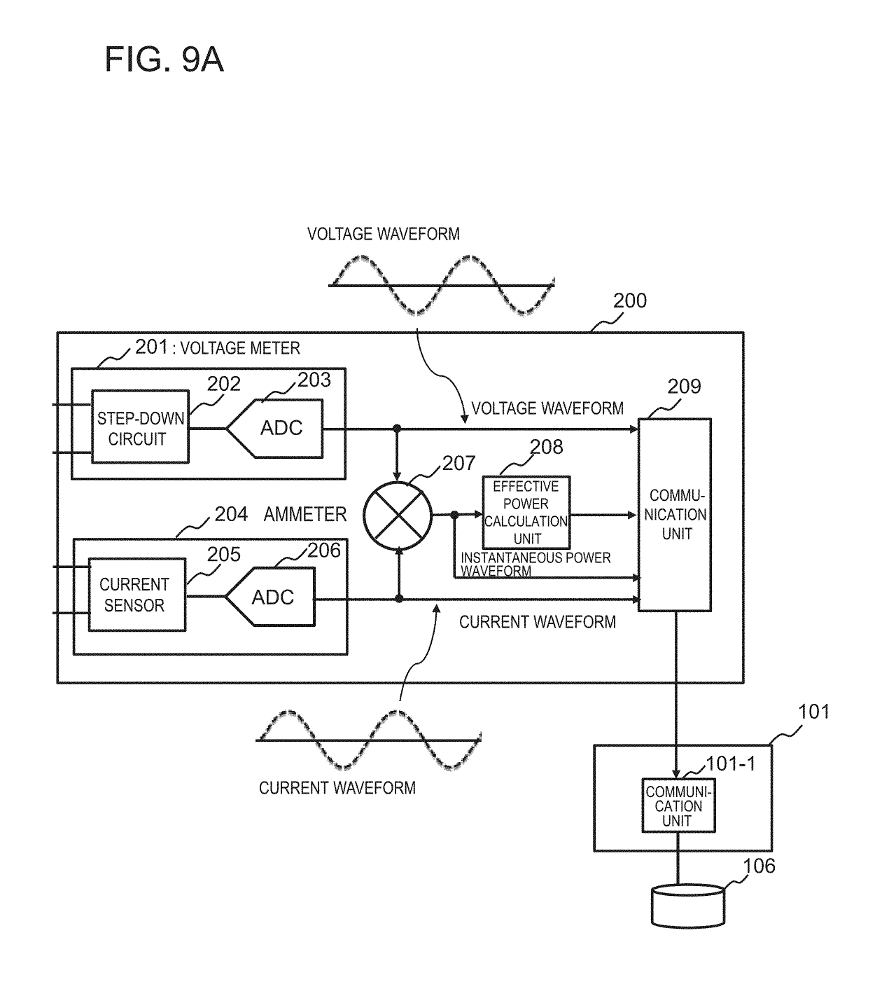

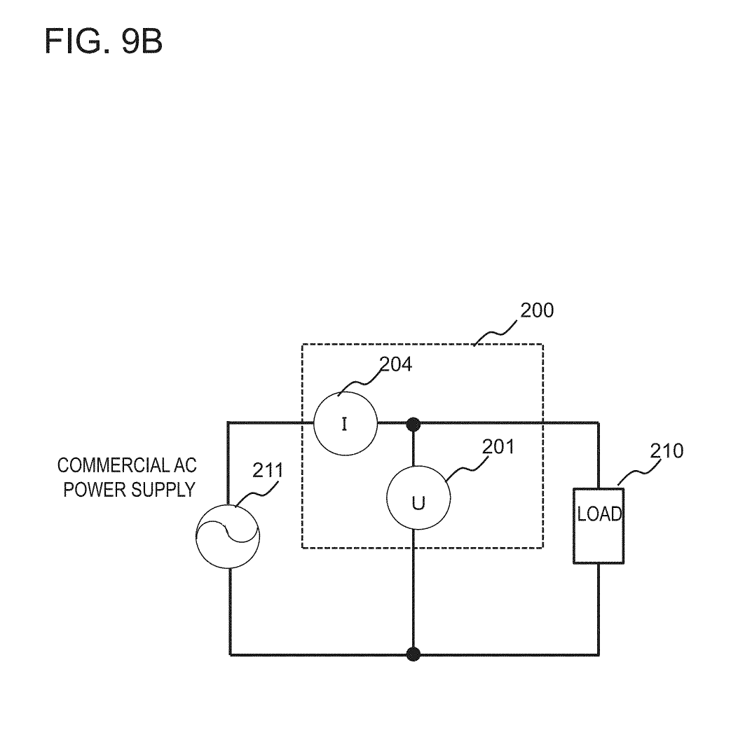

The power/current information acquisition unit 101 acquires, from a sensor 200, time series data of power information and current information of a facility 10 and stores the time series data in the storage apparatus 106. The power/current information acquisition unit 101 may include a communication means (101-1 in FIG. 9A), for example, communicates with the sensor 200 (in FIG. 9A) via the communication means, and may acquire the time series data of power information and current information of the facility 10 that have been measured by the sensor 200.

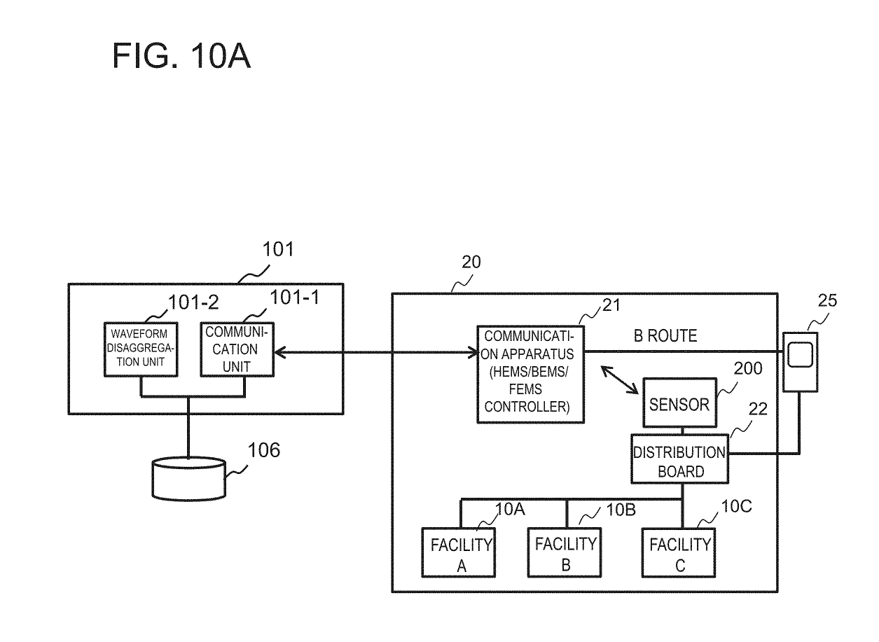

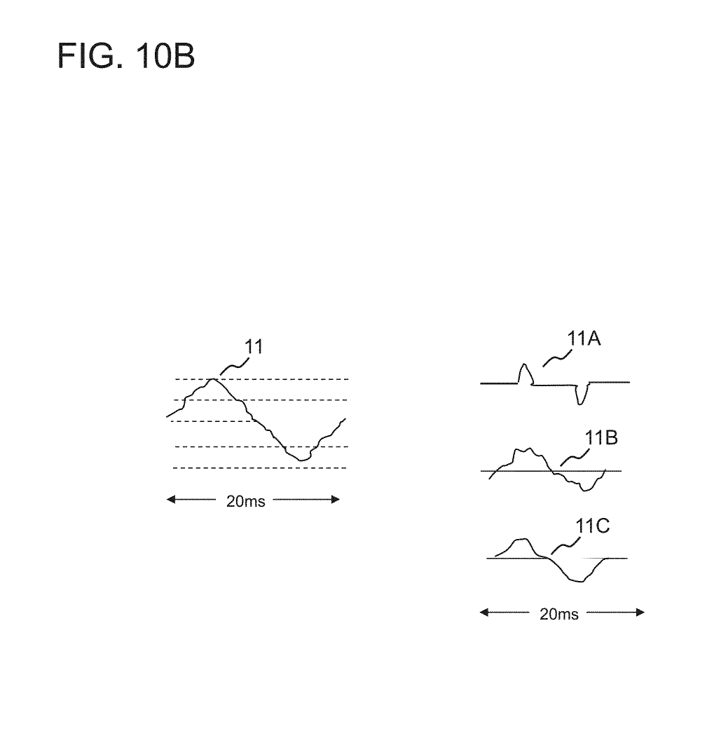

Alternatively, the power/current information acquisition unit 101 may include a communication means (101-1 in FIG. 10A), acquire current information from the sensor 200 (current sensor) or the like connected to a distribution board (22 in FIG. 10A) configured to supply power to one or a plurality of facilities 10 and may acquire power consumption and current information of an individual facility using disaggregation technology. Alternatively, a smart meter (25 in FIG. 10A) provided in a building of a house, a factory, a shop, or the like may be used as the sensor 200, and the power/current information acquisition unit 101 may acquire current information from the smart meter via a communication means not illustrated to obtain the power consumption and current information of an individual facility using a disaggregation technology.

In the sensor 200, a sampling rate of power of the facility 10 and a sampling rate of current of the facility 10 may be the same. Alternatively, they may be not the same. Preferably, a correspondence relationship between a sampling timing of power and a sampling timing of current information (current waveform) may be held. The power of the facility may be an effective power obtained by averaging (smoothing) an instantaneous power over one cycle ( 1/50=20 milliseconds) or a plurality cycles of a commercial AC power supply from a time (T1) (this effective power is referred to power consumption).

The sensor 200 stores and holds, with regard to information on the power sampled at the time (T1), time series data of the current information sampled over a period corresponding to a plurality cycles of the commercial AC power supply from the time (T1) at a predetermined sampling rate (such as 20 kHz), in association with the time (T1). The sensor 200 may be configured to acquire a voltage waveform, in addition to a current waveform, and supply the voltage waveform and the current waveform to the power/current information acquisition unit 101. The power/current information acquisition unit 101 may be configured to partition the time series data of a current waveform into a plurality cycles of the commercial AC power supply after adjusting a phase difference (ϕ: power factor angle) of the current waveform to a voltage waveform based on a zero cross point of data of the voltage waveform, for example. The power/current information acquisition unit 101 may be configured to acquire, from the sensor 200, voltage and current waveforms of the facility to calculate an effective power of the facility.

The target segment extraction unit 102 extracts a time segment with respect to each of the time series data of the power information and the current information obtained by the power/current information acquisition unit 101 and stored in the storage apparatus 106, wherein the time segment reflects a change with time and is to be targeted for estimation of the change with time of the state of the facility.

In that case, the target segment extraction unit 102 may exclude, from the time series data of the power information, a time segment that does not reflect influence of the change with time at all or scarcely reflects influence of the change with time (or can ignore influence of the change with time) and is to be excluded from an estimation target of a change with time of a state.

Generally, it is possible to estimate that a time segment in which power consumption of a facility gently transitions represents one operating state (operating mode or operation mode) is possible. Further, generally, a time unit of an operating mode (operation mode) of a facility is in order of several minutes to several ten minutes or several hours, for example, and is far larger than a cycle (20 milliseconds) of the commercial AC power supply.

Therefore, the target segment extraction unit 102 may perform extraction of a time segment that is to be targeted for estimation of a change with time of a state of a facility, based on a power value, for example. However, the target segment extraction unit 102 may perform extraction of a time segment that is to be targeted for estimation of a change with time of a state of a facility, based on current information (on a current waveform pattern or a feature value), instead of a power value. Alternatively, the target segment extraction unit 102 may combine power information and current information to perform extraction of a time segment that is to be targeted for estimation of a change with time.

The target segment extraction unit 102, for example, extracts, from the time series data of the power information of the facility, data of a time segment in a specific operating mode of the facility (such as an intermittent operation of an air conditioner, a refrigerator, or the like or a defrost operation of a business use freezer or the like).

The target segment extraction unit 102 may be configured to extract a time segment that is to be targeted for estimation of a change with time at a point of time when time series data of a preset length has been accumulated in the storage apparatus 106. Alternatively, though no particular limitation is imposed, the target segment extraction unit 102 may be configured to periodically operate at a predetermined time or the like once in a day, for example, and extract, from time series data of power of the faculty accumulated in the storage apparatus 106, a time segment that is to be targeted for estimation of a change with time.

The target segment extraction unit 102 may be configured to specify, from time series data of a power value, a time segment of a predetermined operating mode (an intermittent operation, for example), based on operating (operation) history (log) information (e.g., history information of an intermittent operation from what time to what time, or the like) of the facility 10 and time information (such as time stamp information regarding a time of sampling done in the sensor 200) of a power value acquired by the power/current information acquisition unit 101, exclude (delete) the time segment, and extract the time series data in the remaining time segment(s), as an analysis target. In this case, the operation history (log) of the facility 10 is held in a storage apparatus (such as the storage apparatus 106). The operation history of the facility 10 may be stored in the storage apparatus 106 from a production management apparatus not illustrated, via a communication means.

The target segment extraction unit 102 sets, as a time segment of an analysis target, a time segment(s) of time series data of current information (current waveform, feature value, or the like) corresponding to the time segment extracted(s) of a power.

The state estimation unit 103 estimates a state of the facility, based on current information (current waveform, feature value, or the like) in the time segment of the analysis target set by the target segment extraction unit 102.

The state estimation unit 103 may be configured to calculate a feature value of current information (current waveform) based on a waveform shape in a time domain (using a peak value, an effective value (Root Mean Square value (RMS), a mean value, a wave height value or the like), or may set a waveform pattern as a feature value. Alternatively, the state estimation unit 103 may be configured to by applying Fourier Transform (such as a fast Fourier transform (Fast Fourier Transform: FFT) or a discrete Fourier transform (Discrete Fourier Transform: DFT) or the like), current waveform data to convert the current waveform data to a frequency domain and calculate a feature value based on frequency spectrum components. The state estimation unit 103 may calculate a feature value of a current, based on a value obtained by adding squares of each of amplitudes of high-harmonic components of an AC power supply frequency that is a fundamental frequency, or calculate a value obtained by adding squares of each of amplitudes of even-order high harmonic frequency components or odd-order high-harmonic components, for example. Alternatively, a total harmonic distortion (THD) or the like may be used as a feature value of a current. The state estimation unit 103 may be configured to calculate a feature value of a current, based on frequency spectral components of high frequency components extracted by a high-pass filter (HPF), for an air conditioning facility that includes an inverter configured to produce a high-frequency noise on a power supply line or the like.

The state estimation unit 103 may be configured to perform machine learning with respect to each state of a facility and current information (waveform, feature value(s), or the like), for example, to estimate a state (or a change in a state) of the facility, based on extracted current information (waveform, feature value, or the like).

In the machine learning configured to classify input data into two classes, for example, using a linear discriminant function, the learning is performed so that for an input vector: x=(x1, x2, . . . , xd) (dimension number is assumed to be d) of current information (current waveform or feature value) or the like, it is set that an output becomes +1 (class 1: state 1) in a specific state and otherwise, an output becomes −1 (class 2: other than the state 1). In this case, with respect to

y=f(x)=sign(w^{T}x)=sign(w₁x₁+w₂x₂+. . . +w_{d}x_{d})

(where
sign( ) is a sign function which takes +1 if an argument is 0 or more, and −1 if the argument is less than 0,
w=(w₁, w₂, . . . , w_{d}) is a model parameter (weight), and
T is a transposition operator.),
the weight w is adjusted such that

w^{T}x>0 holds with respect to data whose output is y=+1 (class 1), while w^{T}x<0 holds with respect to data whose output is y=−1 (class 2), and the input and the output of supervised data (training data) can be reproduced.

As a supervised learning, a method such as a support vector machine (SVM), a k-nearest neighbor method (k-NN method), or a neural network (NN) may be used. As an unsupervised learning, k-means method (k-Means Clustering Method) or the like may be used.

Alternatively, the state estimation unit 103 may be configured to employ a model configured to quantify a state (such as a deterioration degree) of a facility and determines an expression f that can approximate a state of the facility, by a regression analysis or the like, for example, based on a state of the facility corresponding to time series data of current information (current waveform or feature value), and estimate a state f(x_{N}) of the facility (such as a deterioration degree) corresponding to current information x_{N} at a time t_{N}. When a state of the facility that is estimated at the time t_{N} changes by a predetermined value (threshold value) or more from a state of the facility that was estimated at a time t_{N-1} or before the time t_{N-1}, for example, the state of the facility is estimated to have changed at the time t_{N}. In this case as well, the state estimation unit 103 may be configured to learn the threshold value for determining a change in a state of the facility based on machine learning or the like to detect the change in the state.

The change with time estimation unit 104 performs, for an estimated state (change in a state), a filtering process corresponding to a time change ratio (time constant) of a change with time of an estimation target to estimate a change with time of the state.

A time constant τ corresponds to a time period t=τ to be required for a rising waveform (with an amplitude Y₀): Y(t)=Y₀(1−exp(−t/τ) of an exponential characteristic to reach 0.632 Y₀ (Y(τ)=Y₀(1−exp(−1))≈0.632 Y₀) from an initial value 0. Similarly, the time constant τ corresponds to the time period t=τ to be required for a falling waveform Y(t)=Y₀ exp(−t/τ) of the exponential characteristic with an initial value Y₀ to reach Y(τ)=Y₀ exp(−1))≈0.368 Y₀) from the initial value Y₀.

When a change with time (temporal change) in a state of a facility does not have an exponential characteristic, the above-described definition of the time constant cannot be applied to the change with time of the state of the facility without alteration. In conformity with the filtering process (in which a cutoff frequency fc of a low-pass filter is, for example, 1/(2πτ): τ is a time constant) associated with the change with time of a state, the term “time constant” is herein used for the change with time of the state of the facility as well.

The change with time estimation unit 104 extracts a change with time of a state which is extracted corresponding to a time constant for a change with time of an estimation target, as a result of estimation of the change with time of a state of the facility.

Assume, for example, that a filter of an air conditioner is blocked by an object (placed object such as a baggage) and a change with time that is more abrupt than a change with time caused by clogging of the filter or the like has occurred in a state (deterioration state) of the air conditioner. In this case, by applying a filtering process in which a time constant τ is relatively small (high-pass filtering process) to a state of an analysis target time segment, an abrupt change with time of the state can be extracted. Further, by applying a filtering process in which a time constant τ is relatively large (low-pass filtering process), a change with time caused by a clogging of the filter or the like, with exclusion of a deterioration state caused by a clogging by a baggage or the like can be extracted.

The filtering process to be performed by the change with time estimation unit 104 may be implemented by applying a Fourier transform (such as a fast Fourier transform or a discrete Fourier transform) to time series data of a signal value, each indicating a deterioration degree (also referred to as a “danger degree with respect to a failure”) of the facility (wherein the signal value may also be a current waveform or a feature value of the current waveform) to convert the time-series data to a frequency domain, applying a process of cutting off a predetermined frequency band of a frequency spectrum, and applying an inverse Fourier transform to return the time series data in a time domain. A Fourier transform may be performed for the time series data of the current information having a positive correlation with the deterioration degree of the facility. Alternatively, a digital filtering process such as FIR (Finite Impulse Response) filter or an IIR (Infinite Impulse Response) in time domain may be used as the filtering process.

The output unit 105 outputs the result of the estimation of the change with time of the state of the facility to a display apparatus. Alternatively, it may be so configured that the output unit 105 transmits the result of the estimation of the change with time of a state of the facility to a terminal, a host, or the like not illustrated via a communication interface, a network, or the like not illustrated.

FIG. 9A is a diagram illustrating an example of a configuration of the sensor 200 in FIG. 1. Though FIGS. 9A and 9B each illustrate a single-phase two-wire AC, for simplicity, a three-phase three-wire AC can also be measured by using three single-phase power meters. Alternatively, power measurement based on a two-power meter method may be performed. Referring to FIG. 9A, the sensor 200 may be configured to include a voltage meter 201 (U in FIG. 9B) configured to measure a voltage between terminals of a facility (load 210 in FIG. 9B) and an ammeter 204 (I in FIG. 9B) configured to measure a current flowing in the facility (load 210 in FIG. 9B). The voltage meter 201 may be configured to include a step-down circuit 202 configured to reduce a voltage between the terminals of the load (210 in FIG. 9B) and an analog-to-digital converter 203 configured to convert an analog output voltage of the step-down circuit 202 to a digital signal. The ammeter 204 may be configured to include a current sensor 205 configured to detect a current flowing through a power supply line (power supply line connected to the load 210 in FIG. 9B) and an analog-to-digital converter 206 configured to convert an analog output signal from the current sensor 205 to a digital signal. The current sensor 205 may be configured to measure a voltage between terminals of a shunt resistor (not illustrated) inserted in a power supply line, for example. Alternatively, the current sensor 205 may be formed of a hole element, a CT (Current Transformer: a zero-phase-sequence current transformer (Zero-phase-sequence Current Transformer: ZCT) or the like), or the like. The CT has a structure of a current transformer with coils wound around a magnetic core or the like and detects a current by inserting a cable of a target for current measurement therethrough and performing conversion using a detection value of a magnetic flux flowing through the magnetic core.

Voltage waveform data from the analog-to-digital converter 203 of the voltage meter 201 and power waveform data from the analog-to-digital converter 206 of the ammeter 204 are multiplexed by a multiplexer 207 to obtain an instantaneous power waveform. An effective power calculation unit 208 performs smoothing of the instantaneous power waveforms over predetermined cycles to calculate an effective power value. Current waveform data associated with the power information (effective power value) is supplied to a communication unit 209 and is transmitted to the power/current information acquisition unit 101. It may be so configured that the communication unit 209 transmits the power information (effective power value) and the voltage waveform data and the current waveform data associated therewith to the power/current information acquisition unit 101, together with measurement time information.

A communication unit 101-1 of the power/current information acquisition unit 101 communicates with the communication unit 209 of the sensor 200, receives an effective power, and time series data of a measured voltage and current and stores the received time series data in the storage apparatus 106. The communication unit 101-1 may be configured to store time information of power and current measured by the measuring instrument 200 in the storage apparatus 106, in association with time series data of the power (effective power) and current. The power/current information acquisition unit 101 may be configured to perform partitioning of time series data of current for each cycle of a commercial AC power supply (211 in FIG. 9B) to store the partitioned data in the storage apparatus 106, by utilizing a zero cross point(s) of time series data of a voltage waveform. According to this example embodiment, a high-performance power meter is not needed for the sensor 200 in FIG. 9A and FIG. 9B.

As described above, the power/current information acquisition unit 101 is not, of course, limited to a configuration connected to the sensor 200 or a configuration including the sensor 200. It may be so configured that the power/current information acquisition unit 101 performs waveform disaggregation of a current waveform acquired from a smart meter, a current sensor, or the like to obtain power consumption and a current waveform (whose length is within one cycle of a commercial power supply frequency, for example) for each facility. In this case as well, a high-performance power meter is not needed.

FIG. 10A is a diagram explaining an example in which the power/current information acquisition unit 101 performs disaggregation of a power supply current waveform into an individual current waveform of each facility, using the sensor 200 installed on a main breaker or a branch breaker of the distribution board or a smart meter 25, as the sensor 200 in FIG. 10. Referring to FIG. 10A, a communication apparatus 21 is configured with a controller such as a HEMS/BEMS/FEMS in a building 20 and meter reading data (power consumption, current waveform or the like) of the smart meter 25 is acquired via a B route, for example. The meter reading data (power consumption, current waveform or the like) that the communication apparatus 21 acquires from the smart meter 25 via the B route includes information on power consumption of the building 20 as a whole. Further, the sensor 200 configured to detect power and a current, for example, is provided with at least one branch breaker (not illustrated) or a main breaker of a distribution board 22. Power and current information may be transmitted from the sensor 200 to the communication apparatus 21 by wireless transmission or the like. The sensor 200 may perform wireless transmission of the power and current information to the communication apparatus 21 using a Wi-SUN (Wireless Smart Utility Network) or the like.

The power/current information acquisition unit 101 includes a communication unit 101-1 and a waveform disaggregation unit 101-2. The communication unit 101-1 communicates with the communication apparatus 21 and acquires power and current information (overall power and current information) acquired by the sensor 200 or the smart meter 25, performs disaggregation of the power and current information into an individual power and an individual current waveform of each individual facilities A to C (10A to 10C), and stores the power and the current waveform in the storage apparatus 106. A current waveform 11 in FIG. 10B is a graph illustrating a current waveform (a combined current waveform of individual current waveforms of the facilities A to C) acquired by the sensor 200 which is installed on the distribution board 22 in FIG. 10A. The waveform disaggregation unit 101-2 performs disaggregation of the current waveform 11 in FIG. 10B into current waveforms 12A to 12C of individual facilities A to C (10A to 10C), using a method according to Non-Patent Literature 1 or the like, for example. Current waveforms 11A to 11C in FIG. 10B schematically illustrate disaggregated current waveforms for each of individual facilities A to C (10A to 10C). In the case of the configuration in FIG. 10A, cost reduction can be more remarkably performed than in the case where the sensor 200 is provided with the facility 10 (in FIG. 9A).

The waveform disaggregation unit 101-2 in the power/current information acquisition unit 101 in FIG. 10A may be configured to be arranged in the building 20 on a local side or the like (in this case, the storage apparatus 106 may be configured to be disposed on a cloud side in this case).

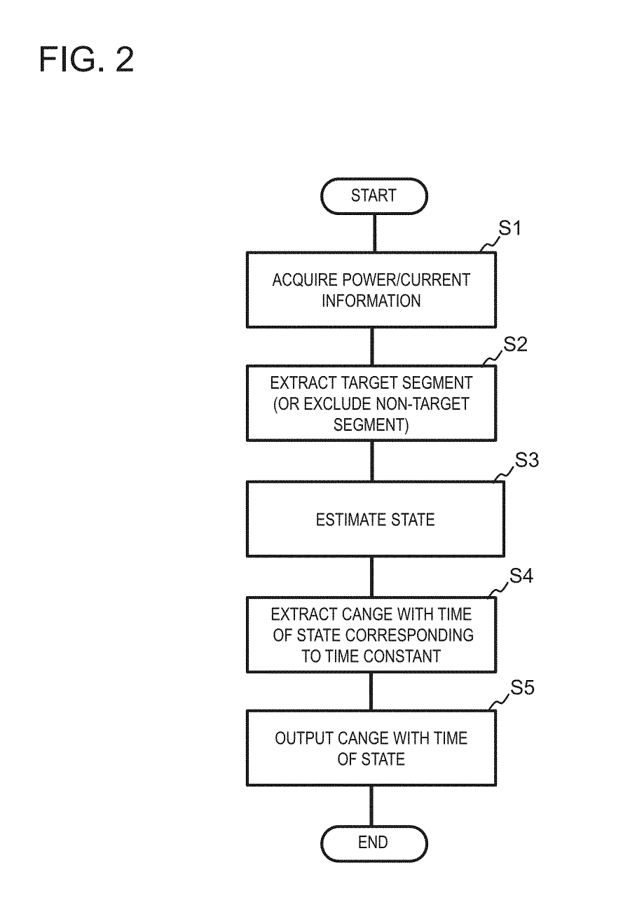

FIG. 2 is a diagram explaining an example of a processing procedure in the example embodiment described with reference to FIG. 1 and so on.

The power/current information acquisition unit 101 in FIG. 1 acquires time series data of power/current information of a facility (S1).

The target segment extraction unit 102 in FIG. 1 extracts a time segment for an operating mode, which reflects a change with time in the time series data of the power/current information (S2). The target segment extraction unit 102 may be configured to exclude a time segment for an operating mode which does not reflect a change with time in the time series data of the power/current information, as a result which the target segment extraction unit 102 extracts the time segment for the operating mode, which reflects a change with time.

The state estimation unit 103 in FIG. 1 estimates a state of the facility from the time series data of current information in the time segment that has been set by the target segment extraction unit 102 (S3).

The change with time estimation unit 104 in FIG. 1 extracts a result of estimation of the change with time corresponding to a time constant for the change with time to be extracted (S4).

The output unit 105 in FIG. 1 outputs the result of the estimation of the change with time of a state of the facility (S5).

According to the example embodiment, even if a change with time of a state of a facility is minute, by separating the change with time from a time change that is caused by a different factor, with filtering or the like, it is possible to make an appropriate estimation of the change with time. As a result, it becomes possible to make a precise identification of maintenance of a facility or a cleaning time.

It may be so arranged that in case wherein current information is used, information on various change with times (such as a temperature change detected by a temperature sensor, a vibration change detected by a vibration sensor, or information on a cleaning date, information on a temporal deterioration, and so forth) may be observed together.

According to the example embodiment, by performing the following (a) and (b), information on a change with time corresponding to a desired length with respect to a state change of the facility can be appropriately estimated. As a result, the change with time can be detected with practical accuracy while suppressing an increase in cost.

(a) The target segment extraction unit 102 in FIG. 1 extracts, from time series data of power of a facility, a time segment (period) that is influenced by a change with time targeted for estimation.

(b) The state estimation unit 103 in FIG. 1 estimates a state (state change) of a facility in an extracted time segment and the change with time estimation unit 104 applies a filtering process or the like according to a time constant for a change with time of an extraction target to extract a change with time of a state.

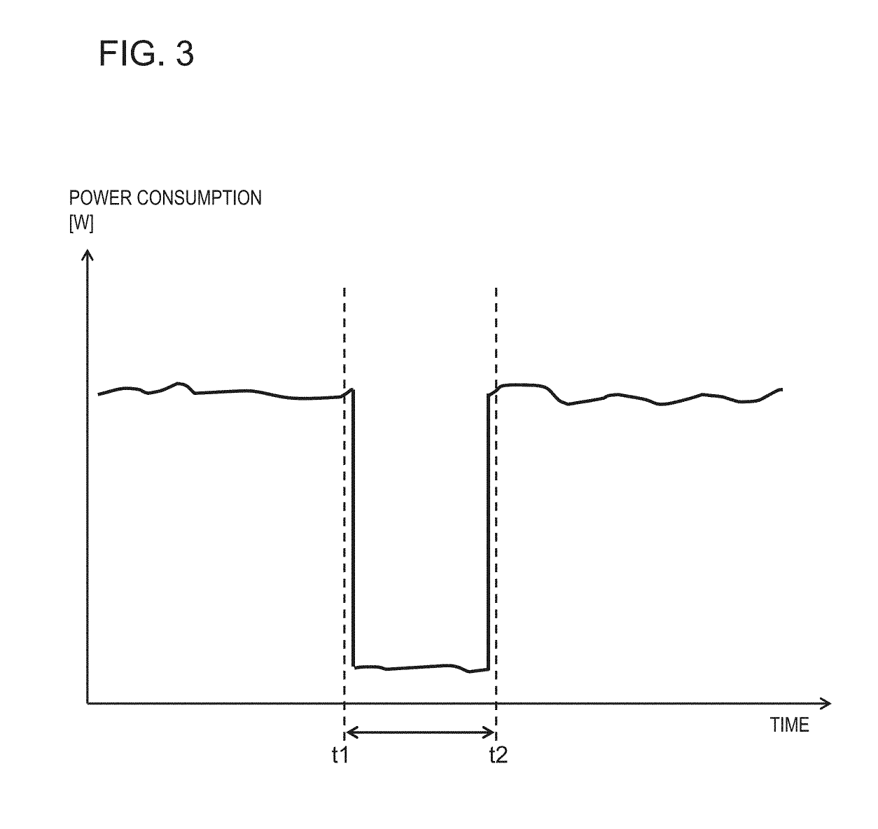

In the above-described process (a), as illustrated in FIG. 3, for example, a time segment from times t1 to t2 is a period of an OFF (such as a stop) state in an intermittent operation (where operation and stop are alternately repeated with a certain period interposed therebetween) of the facility.

The target segment extraction unit 102 in FIG. 1 excludes the time series data of power in this time segment from the time series data of an analysis target because the time series data of power in this time segment is not information that has been influenced by a change with time. Referring to FIG. 3, a horizontal axis indicates time and a vertical axis indicates power consumption. It may be so configured that, in order to obtain the time series data in FIG. 3, the power/current information acquisition unit 101 acquires, from the sensor 200, a predetermined length (of several minutes, for example) of time series data of power information of the facility 10, for each constant period of time (such as one hour) and stores the time series data: (time, and power consumption) as illustrated in FIG. 3 in the storage apparatus 106, as a table. Sampling of the time series data does not necessarily need to be carried out at equal time intervals.

The target segment extraction unit 102 in FIG. 1 may determine an operating mode (intermittent operation) of a facility in the time segment from the t1 to the t2 in FIG. 3 by using an operation history of the facility or using a power value(s) or the like of the facility acquired by the power/current information acquisition unit 101.

In the above-described process (b), the change with time estimation unit 104 in FIG. 1 uses a filtering process or the like according to a time constant for a change with time of an extraction target to perform the extraction. FIG. 4 is a graph explaining an example of a change with time of a state, when two cases of filter clogging of an air conditioner and blocking of the air conditioner by an object (such as a placed object of a baggage or the like) in an air conditioning facility have been overlapped. Referring to FIG. 4, a horizontal axis indicates time and a vertical axis indicates a danger degree with respect to a failure (degree of danger to be caused by a change with time). A deterioration state gently progresses with time due to filter clogging of the air conditioner. When an object that blocks a filter of an outdoor unit of the air conditioner is placed, the danger degree with respect to a failure abruptly rises at a time t3. When the object that has blocked the filter is removed at a time 4, the danger degree returns to a time transition (change with time) of the danger degree with respect to a failure caused by the filter clogging alone.

The danger degree with respect to a failure on the vertical axis in FIG. 4 may be such one obtained by quantifying a deterioration state of the facility. Alternatively, the danger degree with respect to a failure may be a signal (such as a current that flows in the facility) having a positive correlation with the danger degree with respect to a failure (deterioration state of the facility).

The change with time estimation unit 104 in FIG. 1 applies a filtering process (using a low-pass filter: cut-off frequency=1/(2πτ)) corresponding to the time constant τ for filter clogging to allow separation and extraction of the degree of progress of the filter clogging.

The change with time estimation unit 104 in FIG. 1 can discriminate and extract a state change caused by blocking by an object (baggage) by using the filtering process (using a high-pass filter) with a cut-off frequency corresponding to the filter closing and the blocking by the object (baggage).

While filter clogging is a component that slowly changes over a period of approximately several days to several weeks, a change in which an object (baggage) that blocks the filter has been placed or removed is a quick change of approximately several minutes to several hours, and these changes can be clearly discriminated and determined by the filtering process.

As described above, according to the example embodiment, by focusing on a time change of a target change with time phenomenon, influence of the change with time can be appropriately estimated. Therefore, according to the example embodiment, it becomes possible to prompt appropriate handling such as preventive maintenance, according to enabled estimation of a change with time of a state of the facility.

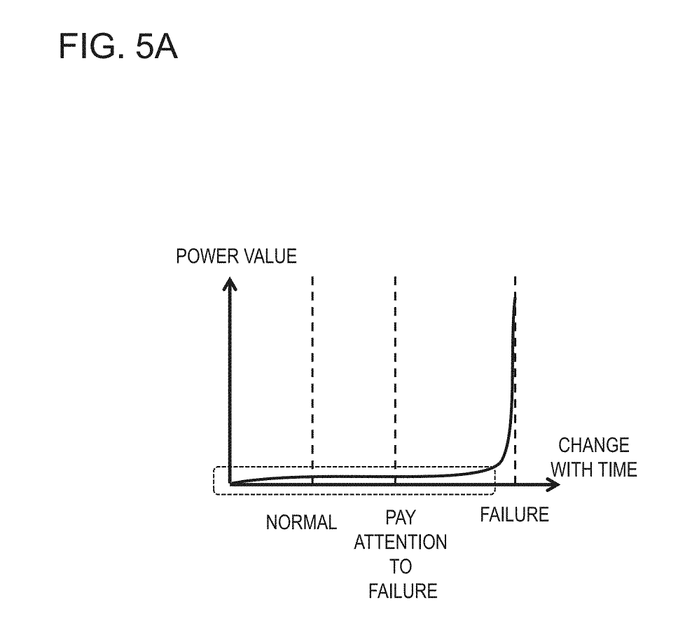

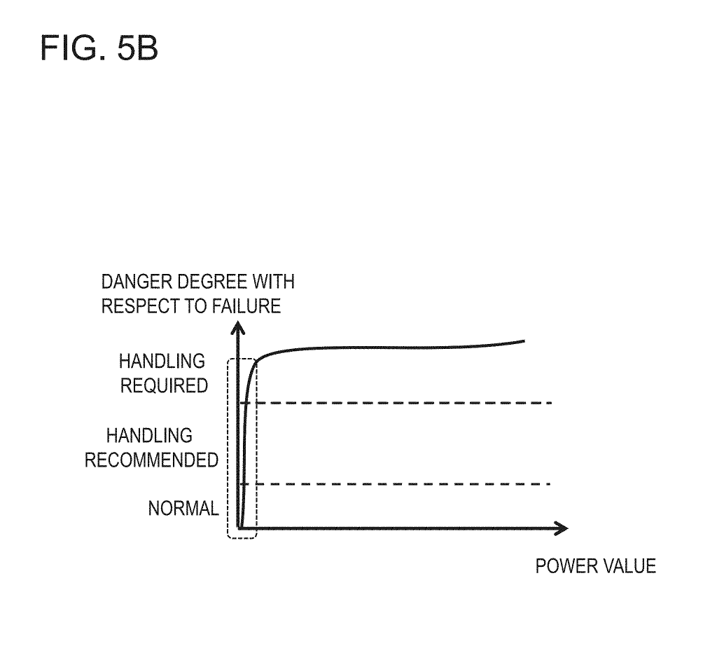

FIG. 5A is a graph explaining a relationship between a power value and a change with time of the facility 10 in FIG. 1. A horizontal axis indicates a change with time (state of the facility), and a vertical axis indicates a power value of the facility. A time change of the power value from “normal” to “pay attention to failure” on the horizontal axis is small. The power value rises immediately before a failure. When a failure occurs, the power value indicates a remarkable rise. As illustrated in FIG. 5A, a deterioration of the facility does not appear as a power value difference until the deterioration of the facility has considerably progressed. Each power value in a range enclosed by a broken line does not appear as a remarkable difference with respect to a progress of the deterioration of the facility (a power value change amount is small).

FIG. 5B is a graph explaining a relationship between a power value in FIG. 5A and a danger degree with respect to a failure. A horizontal axis indicates the power value and a vertical axis indicates the danger degree with respect to failure of a facility (corresponding to the vertical axis in FIG. 4). “Handling Recommended” for the danger degree with respect to a failure indicates that a handling of maintenance is in a state of recommendation, and “Handling Required” indicates that a maintenance is necessary.

Referring to FIG. 5A and FIG. 5B, when a power consumption exceeds a rated power of the facility, a further deterioration or destruction of a product may occur, in addition to an original failure. When a failure occurs, an electric power supply to the facility is shut off (shut off by a breaker when overcurrent is detected in the facility or when a short-circuit failure occurs, or the like, for example), or the facility itself does not operate.

It can be seen from FIG. 5B that the danger degree with respect to a failure abruptly changes from “Normal” to “Handling Recommended”, and to “Handling Required”, for a slight change in the power value. Therefore, the power value is not suited for detection of a failure sign or the like.

Referring to FIG. 5A, a high-performance power meter is needed for detection of a change with time from “Normal” to “Pay Attention to Failure” or the like, using a power value. Therefore, it is conceived that, in case wherein power consumption information of individual facility is obtained from a current waveform detected by the sensor 200 connected to the distribution board, by using a disaggregation technology described in Non-Patent Literature 1 or the like, detection of a slight power value change or the like is difficult.

Accordingly, in the example embodiment, estimation of a state (with respect to a deterioration degree or an anomaly) of a facility is performed by analyzing information of a current flowing through the facility.

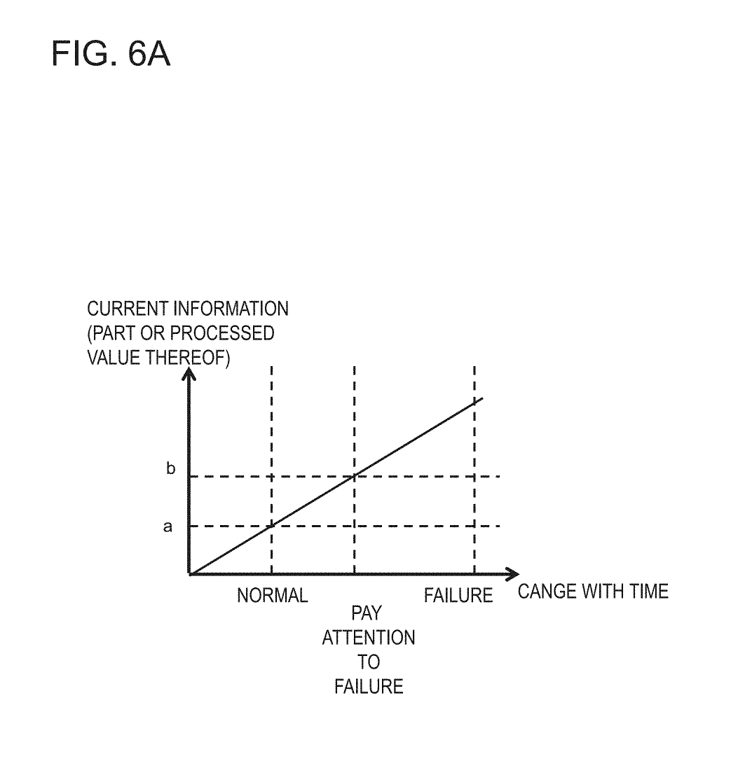

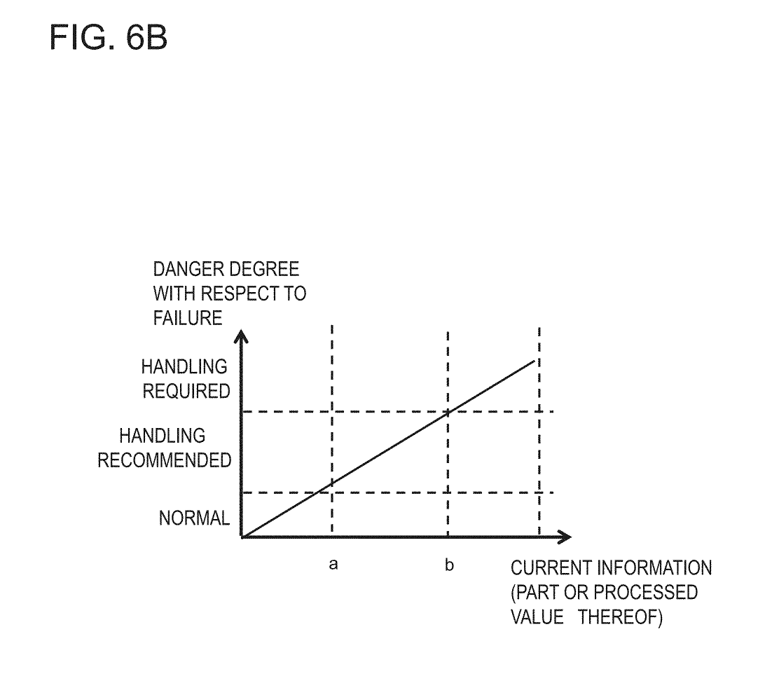

FIG. 6A is a graph explaining a relationship between current information of a facility and a change with time. A horizontal axis indicates the change with time, and a vertical axis indicates current information (part or processed value of current) of the facility. The current information changes (monotonously increases) at a certain rate until a failure occurs. A part of the current information can be made to correspond to a time segment of a unit of time series data of the current information. A feature value described above may be used as a processed value of the current information.

FIG. 6B is a graph explaining a relationship between the current information of the facility and the danger degree with respect to a failure. A horizontal axis indicates current information (part or processed value thereof), and a vertical axis indicates a danger degree with respect to a failure of a facility (corresponding to the vertical axis in FIG. 4). The danger degree with respect to a failure changes from normal to handling recommended and to handling required, in proportion with an increase in a current value. a and b of the current information (part or processed value) on the horizontal axis in FIG. 6B respectively correspond to a and b in FIG. 6A.

Since there are the relationships as illustrated in FIG. 6A and FIG. 6B among current information, a change with time, and a danger degree with respect to a failure, the state estimation unit 103 may estimate a state of the facility as a danger degree with respect to a failure by using the current information. The state estimation unit 103 may be configured to obtain a detailed current waveform pattern for each cycle of the commercial AC power supply, compares a feature value extracted from the current waveform or a danger degree with respect to a failure computed based on the current information, with a predetermined threshold value (a or b in one of FIG. 6A and FIG. 6B), to detect “Normal”, “Handling recommended”, “Handling required” or the like.

In case wherein the state estimation unit 103 detects “Normal”, “Handling Recommended”, “Handling Required” or the like in FIG. 6B, a method such as machine learning (e.g., a support vector machine (SVM), a k-nearest neighbor method (k-NN method), a k-means method (k-Means Clustering Method), a neural network (NN), or a local outlier factor method (LOF method) may be used.

FIG. 6A and FIG. 6B respectively illustrate, by straight lines, a relationship between current information and a change with time and a relationship between the current information and a danger degree with respect to a failure, only for simplicity of description. Referring to FIG. 6B, when the danger degree with respect to a failure has the characteristic as illustrated in FIG. 4, it may be so configured that the horizontal axis is divided into a plurality of segments and approximation using a spline curve is performed for each segment.

Referring to FIG. 6B, in case wherein a facility is a manufacturing facility for producing a product, a proportion defective of the product or the like may be used as the danger degree with respect to a failure. When the proportion defective is a predetermined value, the danger degree with respect to a failure becomes handling required. When the proportion defective is one (all the products are defective), it means that a failure has occurred. Regarding an air conditioner or the like, it may be set that the danger degree with respect to a failure=1−cooling COP (Coefficient Of Performance), based on the cooling COP=cooling ability (kW)÷cooling power consumption (kW), wherein the cooling COP is a cooling ability per power consumption of 1 kW (Kilowatt) when cooling is performed.

With respect to information on a change with time, the above-described Patent Literature 3 discloses two methods of:

(1) determining each parameter by fitting of a predefined time characteristic (numerical expression); and
(2) using a difference between a mean value of measured values in a certain range and a latest value of the measured values, as a change with time component.

In the case of (1), it is necessary to know the time characteristic of the change with time to a certain degree based on an experience value of a worker or the like, and further, it is also difficult to discriminate a time characteristic of a change with time from other error factors (such as a measurement error). Thus, it cannot be said that this method enables to extract only a change with time component.

In the case of (2), setting of a time range used for extraction of a time change component is not quantitative though it is not necessary to know the time characteristic in advance, and isolation from other error factors (such as the measurement error) is also difficult. It is difficult to say that this method enables to extract only a change with time component. Accordingly, it cannot be said that Patent Literature 3 can estimate the change with time with good accuracy.

### Specific Example

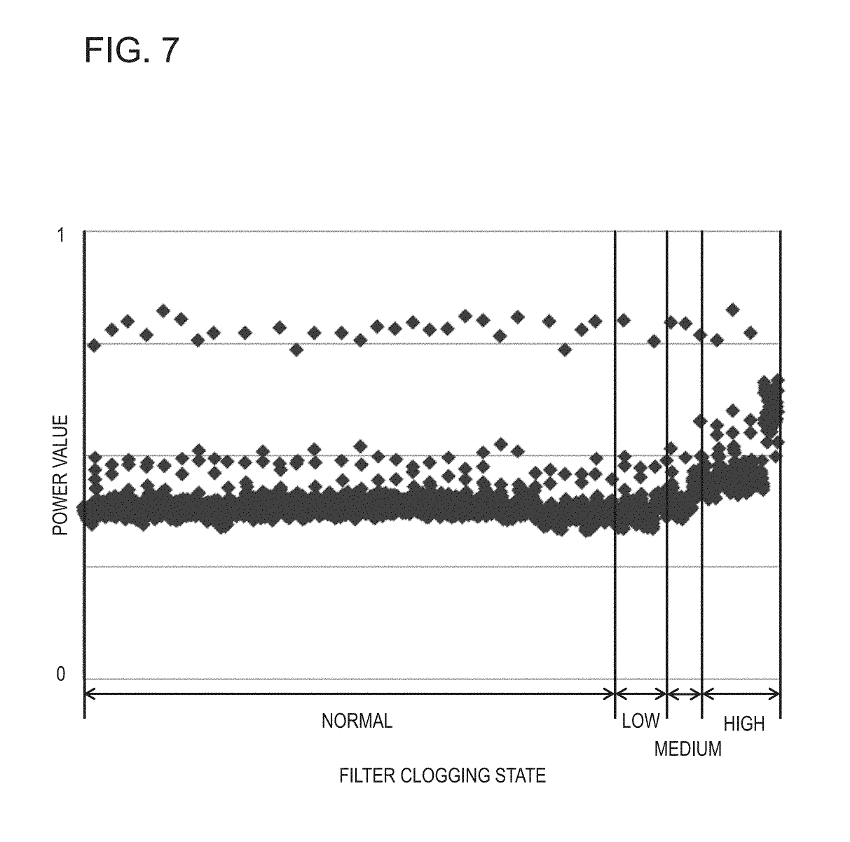

FIG. 7 is a graph indicating an example of measurement of power values when a reproduction experiment of filter clogging of an air conditioner has been conducted. Referring to FIG. 7, a horizontal axis indicates a state of filter clogging, and a vertical axis indicates a power value. As an example, reproduction of the filter clogging has been performed in an ascending order of clogging degrees of four states that are a normal state (no clogging), a low state, a medium state, and a high state. As clear from FIG. 7, it is difficult to detect a power value as a change if reproduction of the clogging of the filter in the high state is not performed. That is, it can be seen from FIG. 7 that determination of a state of the filter clogging based on the power value is difficult, when the degree of the filter clogging is low.

In the demonstration experiment of the filter clogging in the air conditioner in FIG. 7, a time segment in a defrosting operation (where the power value extremely fluctuates because a heater operates) in which an intermittent operation is OFF (stopped or the like) (with substantially zero power consumption) could be excluded, using only a power value (it is noted that the operation history of the facility may be checked).

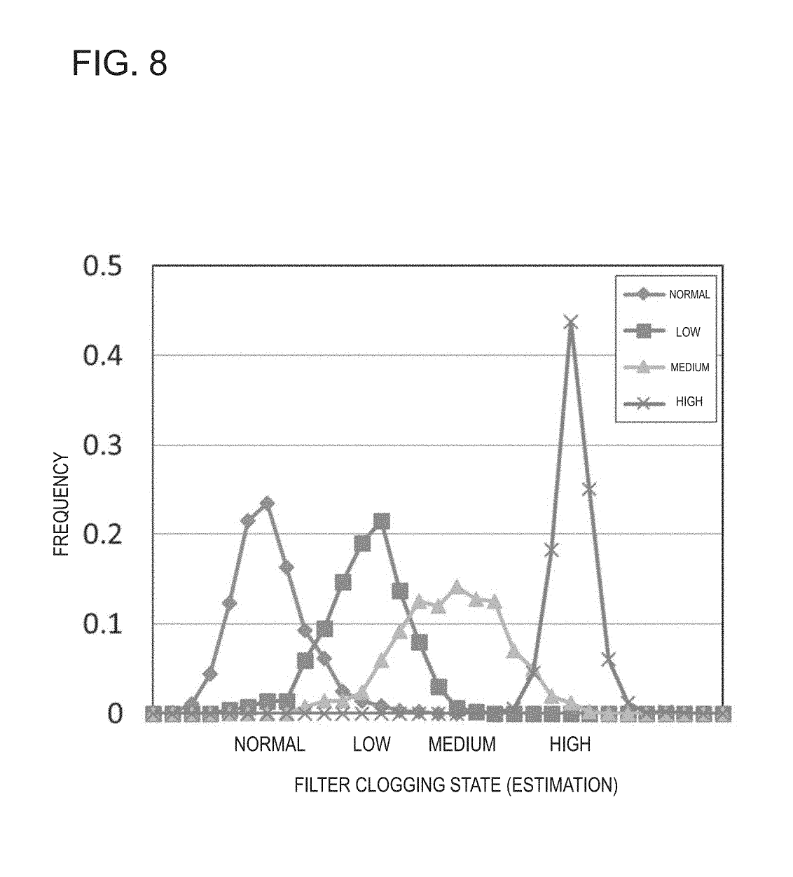

FIG. 8 includes graphs illustrating an example of an experiment result in the demonstration experiment of the filter clogging. FIG. 8 illustrates estimation results of clogging degrees and calculation results of frequency distributions, based on current information. A horizontal axis indicates a state of the filter clogging, and a vertical axis indicates a frequency (normalized to 1). As in FIG. 7, the experiment has been carried out in an ascending order of clogging degrees of four states, that is, in an order of a normal state (with no clogging), a low state, a medium state, and a high state. A rhombus in the drawing is a frequency indicating the normal state, a square (▪) is a frequency indicating the low clogging state, a triangle (▴) is a frequency indicating the medium clogging state, and x is a frequency indicating the high clogging state. Each distribution has a highest frequency in a vicinity of its center, on both left and right sides of the center distributed with substantially the same spreading width. It can be seen from FIG. 8 that when the current information is used, the clogging state can be determination even in the low state of the clogging.

The state estimation apparatus 100 in FIG. 1 may be implemented on a computer system as illustrated in FIG. 11, for example. Referring to FIG. 11, a computer system 110 such as a server computer includes a processor (CPU (Central Processing Unit) or a data processing apparatus) 111, a storage apparatus 112 including at least one of a semiconductor memory (such as a RAM (Random Access Memory), a ROM (Read Only Memory) or an EEPROM (Electrically Erasable and Programmable ROM)), an HDD (Hard Disk Drive), a CD (Compact Disc), a DVD (Digital Versatile Disk), and so on, a display apparatus 113, and a communication interface 114. The communication interface 114 may function as the communication unit (101-1 in each of FIG. 9 and FIG. 10) of the power/current information acquisition unit 101 configured to obtain power and current information acquired by the sensor 200 via a communication network. The output unit 105 of the power/current information acquisition unit 101 in FIG. 1 outputs, to the display apparatus 113, an estimation result of a state change, for example. The storage apparatus 112 may be the same as the storage apparatus 106 in FIG. 1. There may be provided such a configuration that a program to implement functions of the state estimation apparatus 100 in FIG. 1 is stored in the storage apparatus 112 and the processor 111 reads and executes the program, thereby implementing the state estimation apparatus 100 in the above-described example embodiment. The computer system 110 may be implemented as a cloud server configured to provide a state estimation service to a client as a cloud service.

In the above-described example embodiment, the description has been given, using, as an example, time series data of power consumption (in FIG. 3) and time series data of a danger degree with respect to a failure (in FIG. 4) based on power information, as time series data of a signal related to operation of a facility. Information from at least one of a vibration sensor, an acoustic sensor, and a temperature sensor may, as a matter of course, be used.

Each disclosure of the above-listed Patent Literatures 1 to 3 and Non Patent Literature 1 is incorporated herein in its entirety by reference. Modification and adjustment of each example embodiment and each example are possible within the scope of the overall disclosure (including the claims) of the present invention and based on the technical concept of the present invention. Various combinations and selections of various disclosed elements (including each element in each claim, each element in each example, each element in each drawing, and so on) are possible within the scope of the claims of the present invention. That is, the present invention naturally includes various variations and modifications that could be made by those skilled in the art according to the overall disclosure including the claims and the technical concept.

The above-described example embodiments may be described as the following supplementary notes, for example (though not limited thereto).

### Supplementary Note 1

A state estimation apparatus comprising:

a first means that extracts, from time series data of a signal related to an operation of a facility, a time segment of an analysis target; and

a second means that estimates a change with time of a state of the facility, based on the time series data corresponding to the time segment extracted.

### Supplementary Note 2

The state estimation apparatus according to Supplementary Note 1, wherein

the first means excludes, from the time series data of the signal related to the operation of the facility, a time segment corresponding to an operating mode that is not affected by a change with time.

### Supplementary Note 3

The state estimation apparatus according to Supplementary Note 2, wherein

the first means excludes, from the time series data of the signal related to the operation of the facility, the time segment corresponding to the operating mode that is not affected by a change with time, based on operation history information of the facility.

### Supplementary Note 4

The state estimation apparatus according to Supplementary Note 2 or 3, wherein

the first means excludes, from the time series data of power or current of the facility, the time segment corresponding to the operating mode that is not affected by a change with time, based on power information or current information of the facility.

### Supplementary Note 5

The state estimation apparatus according to any one of Supplementary Notes 1 to 4, wherein

the second means estimates a change in the state of the facility from the time series data of the current information of the facility corresponding to the time segment extracted.

### Supplementary Note 6

The state estimation apparatus according to any one of Supplementary Notes 1 to 4, wherein

the second means estimates a change in the state of the facility from the time series data of current information of the facility corresponding to the time segment extracted and applies a filtering process corresponding to a time constant for the change with time of an extraction target to estimate the change with time of the state of the facility.

### Supplementary Note 7

The state estimation apparatus according to any one of Supplementary Notes 1 to 4, wherein

the second means calculates time series data of a danger degree with respect to a failure of the facility, based on the time series data of current information of the facility corresponding to the time segment extracted; and

the second means applies, to the time series data of the danger degree with respect to a failure corresponding to the time segment extracted, a filtering process corresponding to a time constant for a change with time of an extraction target to estimate the change with time of the state of the facility.

### Supplementary Note 8

A state estimation method of estimating a state of a facility by a computer, comprising:

a first step of extracting, from time series data of a signal related to an operation of the facility, a time segment of an analysis target; and

a second step of estimating a change with time of the state of the facility, based on time series data corresponding to the time segment extracted.

### Supplementary Note 9

The state estimation method according to Supplementary Note 8, comprising

in the first step, excluding a time segment corresponding to an operating mode that is not affected by the change with time from the time series data of the signal related to the operation of the facility.

### Supplementary Note 10

The state estimation method according to Supplementary Note 8, comprising

in the first step, excluding, based on operation history information of the facility, the time segment corresponding to the operating mode that is not affected by the change with time.

### Supplementary Note 11

The state estimation method according to Supplementary Note 9 or 10, comprising

in the first step, excluding, based on power information or current information of the facility, the time segment corresponding to the operating mode that is not affected by the change with time is excluded from the time series data of voltage or current of the facility.

### Supplementary Note 12

The state estimation method according to any one of Supplementary Notes 8 to 11, comprising

in the second step, extracting a change in the state of the facility is estimated from the time series data of the current information of the facility corresponding to the time segment.

### Supplementary Note 13

The state estimation method according to any one of Supplementary Notes 8 to 11, comprising:

in the second step, estimating a change in the state of the facility from the time series data of the current information of the facility corresponding to the time segment extracted, and

applying a filtering process corresponding to a time constant for the change with time of an extraction target with respect to the change in the state of the facility to estimate the change with time of the state of the facility.

### Supplementary Note 14

The state estimation method according to any one of Supplementary Notes 8 to 11, comprising:

in the second step, calculating time series data of a danger degree with respect to a failure of the facility, based on the time series data of the current information of the facility corresponding to the time segment extracted; and

applying a filtering process corresponding to a time constant for a change with time of an extraction target to the time series data of the danger degree with respect to a failure corresponding to the time segment extracted to estimate the change with time of the state of the facility.

### Supplementary Note 15

A program causing a computer to execute:

a first process of extracting, from time series data of a signal related to an operation of a facility, a time segment of an analysis target; and

a second process of estimating a change with time of a state of the facility, based on the time series data of the time segment extracted.

### Supplementary Note 16

The program according to Supplementary Note 15, comprising

in the first process, excluding a time segment corresponding to an operating mode that is not affected by the change with time from the time series data of the signal related to the operation of the facility.

### Supplementary Note 17

The program according to Supplementary Note 15, comprising

in the first process, excluding, based on operation history information of the facility, the time segment of the operating mode that is not affected by the change with time.

### Supplementary Note 18

The program according to Supplementary Note 16 or 17, comprising

in the first process, excluding, based on power information or current information of the facility, the time segment of the operating mode that is not affected by the change with time is excluded from the time series data of voltage or current of the facility.

### Supplementary Note 19

The program according to any one of Supplementary Notes 15 to 18, comprising

in the second process, extracting a change in the state of the facility is estimated from the time series data of the current information of the facility corresponding to the time segment.

### Supplementary Note 20

The program according to any one of Supplementary Notes 15 to 18, comprising:

in the second process,

estimating a change in the state of the facility from the time series data of the current information of the facility corresponding to the time segment extracted, and

applying a filtering process corresponding to a time constant for a change with time of an extraction target with respect to the change in the state of the facility to estimate the change with time of the state of the facility.

### Supplementary Note 21

The program according to any one of Supplementary Notes 15 to 18, comprising

in the second process,

calculating time series data of a danger degree with respect to a failure of the facility, based on the time series data of the current information of the facility corresponding to the time segment extracted; and

applying a filtering process corresponding to a time constant for a change with time of an extraction target to the time series data of the danger degree with respect to a failure corresponding to the time segment extracted to estimate the change with time of the state of the facility.

### REFERENCE SIGNS LIST

10, 10A˜10C facility
11, 11A˜11C current waveform
20 building (house)
21 communication apparatus (controller, gateway)
22 distribution board
200 sensor
24 communication apparatus (BEMS/FEMS controller)
25 smart meter
26 high-voltage receiving facility
100 state estimation apparatus
101 power/current information acquisition unit
101-1 communication unit
101-2 waveform disaggregation unit
102 target segment extraction unit
103 state estimation unit
104 change with time estimation unit
105 output unit
106, 112 storage apparatus
110 computer system (apparatus)
111 processor
113 display apparatus
114 communication interface
200 sensor (measuring instrument)
201 voltage meter
202 step-down circuit
203, 206 analog-to-digital converter (ADC)
204 ammeter
205 current sensor
207 multiplier
208 active electricity calculation unit
209 communication unit
210 load (facility)
211 commercial AC power supply

What is claimed is:

1. A state estimation apparatus comprising:
a processor; and
a memory storing program instructions executable by the processor, wherein
the processor is configured to
extract, from time series data of a signal related to an operation of a facility, a time segment of an analysis target; and
estimate a change with time of a state of the facility, based on the time series data corresponding to the time segment extracted.

2. The state estimation apparatus according to claim 1, wherein
the processor is configured to
exclude, from the time series data of the signal related to the operation of the facility, a time segment corresponding to an operating mode that is not affected by a change with time.

3. The state estimation apparatus according to claim 2, wherein
the processor is configured to exclude, from the time series data of the signal related to the operation of the facility, the time segment corresponding to the operating mode that is not affected by a change with time, based on operation history information of the facility.

4. The state estimation apparatus according to claim 2, wherein
the processor is configured to exclude, from the time series data of power or current of the facility, the time segment corresponding to the operating mode that is not affected by a change with time, based on power information or current information of the facility.

5. The state estimation apparatus according to claim 1, wherein
estimates the processor is configured to estimate a change in the state of the facility from the time series data of current information of the facility corresponding to the time segment extracted.

6. The state estimation apparatus according to claim 1, wherein
the processor is configured to estimate a change in the state of the facility from the time series data of current information of the facility corresponding to the time segment extracted and apply a filtering process corresponding to a time constant for a change with time of an extraction target to estimate the change with time of the state of the facility.

7. The state estimation apparatus according to claim 1, wherein
the processor is configured to calculate time series data of a danger degree with respect to a failure of the facility, based on the time series data of current information of the facility corresponding to the time segment extracted, and
apply, to the time series data of the danger degree with respect to a failure, corresponding to the time segment extracted, a filtering process corresponding to a time constant for a change with time of an extraction target to estimate the change with time of the state of the facility.

8. A computer-based state estimation method of a facility, comprising:
extracting, from time series data of a signal related to an operation of the facility, a time segment of an analysis target; and
estimating a change with time of the state of the facility, based on time series data corresponding to the time segment extracted.

9. The state estimation method according to claim 8, comprising
in extracting the time segment, excluding a time segment corresponding to an operating mode that is not affected by a change with time from the time series data of the signal related to the operation of the facility.

10. The state estimation method according to claim 8, comprising
in extracting the time segment, excluding the time segment corresponding to the operating mode that is not affected by a change with time, based on operation history information of the facility.

11. The state estimation method according to claim 8, comprising
in extracting the time segment, excluding the time segment corresponding to the operating mode that is not affected by a change with time, from the time series data of power or current of the facility, based on power information or current information of the facility.

12. The state estimation method according to claim 8, comprising
in estimating the change with time, estimating a change in the state of the facility from the time series data of current information of the facility corresponding to the time segment extracted.

13. The state estimation method according to claim 8, comprising:
in estimating the change with time,
estimating a change in the state of the facility from the time series data of current information of the facility corresponding to the time segment extracted; and
applying a filtering process corresponding to a time constant for a change with time of the extraction target with respect to the change in the state of the facility to estimate the change with time of the state of the facility.

14. The state estimation method according to claim 8, comprising:
in estimating the change with time,
calculating time series data of a danger degree with respect to a failure of the facility, based on the time series data of current information of the facility corresponding to the time segment extracted; and
applying a filtering process corresponding to a time constant for a change with time of an extraction target to the time series data of the danger degree with respect to a failure corresponding to the time segment extracted to estimate the change with time of the state of the facility.

15. A non-transitory computer readable medium storing therein a program causing a computer to execute processing comprising:
extracting, from time series data of a signal related to an operation of a facility, a time segment of an analysis target; and
estimating a change with time of a state of the facility, based on the time series data of the time segment extracted.

16. The non-transitory computer readable medium according to claim 15, wherein the program causes the computer to execute processing comprising
in extracting the time segment, excluding a time segment corresponding to an operating mode that is not affected by the change with time from the time series data of the signal related to the operation of the facility.

17. The non-transitory computer readable medium according to claim 15, wherein the program causes the computer to execute processing comprising
in extracting the time segment, excluding, based on operation history information of the facility, the time segment of the operating mode that is not affected by the change with time.

18. The non-transitory computer readable medium according to claim 16, wherein the program causes the computer to execute processing comprising
in extracting the time segment, excluding, based on power information or current information of the facility, the time segment of the operating mode that is not affected by the change with time is excluded from the time series data of power or current of the facility.

19. The non-transitory computer readable medium according to claim 15, wherein the program causes the computer to execute processing comprising
in estimating the change with time, extracting a change in the state of the facility is estimated from the time series data of current information of the facility corresponding to the time segment.

20. The non-transitory computer readable medium according to claim 15, wherein the program causes the computer to execute processing comprising:
in estimating the change with time,
estimating a change in the state of the facility from the time series data of current information of the facility corresponding to the time segment extracted; and
applying a filtering process corresponding to a time constant for a change with time of an extraction target with respect to the change in the state of the facility to estimate the change with time of the state of the facility.
